(19) United States
(12) Patent Application Publication
(10) Pub. No.: US 2015/0102253 A1
(43) Pub. Date: Apr. 16, 2015

(54) PIEZOELECTRIC MATERIALS FOR LOW SINTERING

(71) Applicant: Samsung Electro-Mechanics Co., Ltd., Suwon (KR)

(72) Inventors: Boum-Seock Kim, Suwon (KR); Hui-Sun Park, Suwon (KR); Jung-Wook Seo, Suwon (KR); Hong-Yeon Cho, Suwon (KR)

(73) Assignee: Samsung Electro-Mechanics Co., Ltd., Suwon (KR)

(21) Appl. No.: 14/150,319

(22) Filed: Jan. 8, 2014

(30) Foreign Application Priority Data
Oct. 10, 2013 (KR) 1020130120827

(51) Int. Cl. H01L 41/18

(52) U.S. Cl. CPC H01L 41/183
USPC 252/62.9 PZ

(57) ABSTRACT

The present invention relates to a piezoelectric material for low sintering and more particularly, to piezoelectric materials for low sintering having a composition formula of Pb(Zr, Ti)O₃—Pb(Ni, Nb)O₃ (hereinafter referring to as ‘PZT-PNN’). The PZT-PNN piezoelectric material according to the present invention shows excellent piezoelectric properties compared to the convention piezoelectric materials even at a low sintering temperature of 950° C. or lower. It thus allows reducing manufacturing cost by using relatively lower-cost electrode materials than Pd or Pt and increasing reliability of operation temperature through improving the glass transition temperature.

### TECHNICAL FIELD

The present invention relates to piezoelectric materials for low sintering and more particularly, to piezoelectric materials for low sintering having a composition formula of Pb(Zr, Ti)O₃—Pb(Ni, Nb)O₃ (hereinafter referring to as ‘PZT-PNN’).

### BACKGROUND ART

Piezoelectric material is an energy converting material from mechanical stress/energy to electrical energy. It is well known that various materials including organic and inorganic materials are able to provide the piezoelectric effect. Piezoelectric ceramics such as Pb(Zr,Ti)O₃ (hereinafter referring to as ‘PZT’) have been used as actuators, transformers, ultrasonic motors, ultrasonic devices and various sensors.

PZT ceramics have been widely used in the electronic-ceramic industry due to high dielectric constant and excellent piezoelectric properties but have some drawbacks such as causing pollution due to high PbO volatility at about 1000° C. and degradation of the piezoelectric properties according to changes in basic compositions.

In addition, in the process of manufacturing stacked ceramics such as MLCCs (multi-layer ceramic capacitors) which require sintering in a state that an internal electrode is coated, it is uneconomical since an expensive Ag/Pd, Ag/Pt electrode including a large amount of Pd or Pt has to be used, instead of a Ag electrode having a low melting point, to maintain the piezoelectric property at a sintering temperature of 1000° C. or higher.

Accordingly, there has been ongoing demand for developing piezoelectric ceramics which are made of piezoelectric materials being able to be sintered at relatively lower temperature than the conventional sintering temperature, for example 950° C. or lower to reduce expensive Pd or Pt content and at the same time maintain the excellent piezoelectric properties.

The prior art of the present invention is KR Publication No. 2009-0005765.

### SUMMARY

An object of the present invention is to provide PZT-PNN piezoelectric materials which are able to be sintered at a temperature of 950° C. or lower and have excellent piezoelectric properties.

According to an aspect of the present invention, there may be provided piezoelectric materials for low sintering having a composition formula of (1-x)Pb(Zr_{(1-y)}Ti_{y})O₃-xPb(Ni_{1/3}Nb_{2/3})O₃ (0.10≦x≦0.20, 0.40<y<0.70).

In an embodiment of the present invention, there may be provided piezoelectric materials for low sintering having a composition formula of 0.80Pb(Zr_{(1-y)}Ti_{y})O₃-0.20Pb(Ni_{1/3}Nb_{2/3})O₃ (0.40<y<0.70).

In an embodiment of the present invention, the piezoelectric materials for low sintering may be selected to have the composition within the composition range of the morphotropic phase boundary (MPB).

In an embodiment of the present invention, at least one oxide chosen from PbO, CuO, ZnO and MnO₂ may be further added by 0.1 to 10 wt % with respect to the total weight of the piezoelectric material.

In an embodiment of the present invention, the piezoelectric material for low sintering may have a glass transition temperature(Tg) of 280-320° C. or higher.

In an embodiment of the present invention, the piezoelectric material for low sintering may have a coercive electric field of 10 kV/cm or higher.

The piezoelectric material for low sintering may have perovskite structure.

According to another aspect of the present invention, there may be provided a piezoelectric actuator comprising the piezoelectric material for low sintering.

According to an embodiment of the present invention, there may be provided PZT-PNN piezoelectric materials having better piezoelectric properties than the conventional piezoelectric materials even though they are sintered at a low temperature of 950° C. or lower. It thus allows reducing manufacturing cost by using relatively lower-cost electrode materials than Pd or Pt and increasing reliability of operation temperature through improving the glass transition temperature.

### BRIEF DESCRIPTION OF DRAWINGS

FIG. 1 is a graph showing a variation of density according to sintering temperature of the piezoelectric material.

FIG. 2 is a XRD graph of the piezoelectric material according to Example of the present invention.

FIG. 3 is a XRD graph of the piezoelectric material according to a Comparative Example.

### DETAILED DESCRIPTION

The terms used in the description are intended to describe certain embodiments only, and shall by no means restrict the present invention. Unless clearly used otherwise, scientific and technical terms used herein have general meaning which is usually understood by a person skilled in the art. Unless clearly used otherwise, expressions in the singular number include a plural meaning.

The term “piezoelectric material” used in the present invention means a material having a property of converting mechanical energy to electrical energy using crystal polarization, which has piezoelectric(piezo) effect. Examples of the piezoelectric material include single crystals such as crystals, LiTaO₃, LiNbO₃, and ceramics such as zirconium titanate, barium titanate and the like.

The term “sintering” used in the present invention is a method for creating objects from powders by holding in a mold and then heating the result and generally, a sintering temperature of the piezoelectric material is 1000-1100° C. or higher. When an electrode material and a piezoelectric material are sintered at the same time, the melting point of the electrode material is determined depending on the sintering temperature of the piezoelectric material. For example, when the sintering temperature of the piezoelectric material is 1000-1100° C. or higher, the electrode material is used in the form of an alloy including a metal having a melting point of higher than 1000-1100° C. such as Pd. Therefore, it is critical to lower the sintering temperature of the piezoelectric material to reduce the use of costly electrode materials such as Pd. The term “low temperature sintering” used in the present invention means sintering at 950° C. or lower, preferably 900° C. or lower, more preferably 875° C. or lower.

The term “phase boundary” used in the present invention means a region where different crystalline phases are spatially interfaced among states. Generally, it is defined by parameters of temperature and composition and physical constant are uniquely changes at the phase boundary. The term “morphotropic phase boundary (MPB)” used herein means a phase boundary as a result of composition composing the piezoelectric material not as a result of temperature. Physical constant becomes maximum within the phase boundary composition and shows a marked piezoelectric property.

The term “oxide” used herein is an additive to be added after the calcinating process. For example, it functions as a sintering aid to lower a sintering temperature by providing sintering property to piezoelectric materials. Examples of “oxide” include PbO, CuO, ZnO, MnO₂, MnCO₃, SiO₂ and Pb₃O₄, etc. but it is not limited thereto.

The term “glass transition temperature” used herein is a temperature where an amorphous material converts from a fragile state like glass into a molten or viscous state or a temperature where temperature curve gradient for specific volume changes rapidly. The boundary of the temperature is continuous but physical properties of a material are changed massively along the boundary.

The term “coercive electric field value” used herein is the intensity of applied electric field required to reduce the electric flux density on the hysteresis loop of a ferroelectric material to zero

The term “perovskite structure” used herein is crystal structure of the compound represented by the chemical formula of RMX₃ such as PbZrO₃ or PbTiO₃. It is known that the piezoelectric crystal having perovskite structure shows high dielectric and piezoelectric properties in the phase boundary of morphotropic tetragonal and phombohedral phases, which is in the MPB composition range.

According to an aspect of the present invention, there may be provided piezoelectric materials for low sintering having a composition formula of (1-x)Pb(Zr_{(1-y)}Ti_{y})O₃-xPb(Ni_{1/3}Nb_{2/3})O₃ (0.10≦x≦0.20, 0.40<y<0.70).

Here, piezoelectric materials according to the composition formula are Pb(Zr, Ti)O₃—Pb(Ni, Nb)O₃ (hereinafter referred to as PZT-PNN piezoelectric materials). In an embodiment of the present invention, there may be provided piezoelectric materials for low sintering having a composition formula of 0.80Pb(Zr_{(1-y)}Ti_{y})O₃-0.20Pb(Ni_{1/3}Nb_{2/3})O₃ (0.40<y<0.70). In another embodiment, the range of y may be 0.45<y<0.55.

In an embodiment of the present invention, there may be provided a method for preparing a PZT-PNN piezoelectric material for low sintering having a composition formula of (1-x)Pb(Zr_{(1-y)}Ti_{y})O₃-xPb(Ni_{1/3}Nb_{2/3})O₃ (0.10≦x≦0.20, 0.40<y<0.70), the method comprising:

1) preparing a mixture by mixing PbO, ZrO₂, TiO₂, NiO, Nb₂O₅ which are raw materials in a solvent;

2) calcinating the mixture;

3) generating a uniform mixture by milling the calcined mixture;

4) sieving the milled mixture; and

5) sintering the sieved powder after pressure molding.

In an embodiment of the present invention, amount of the law material to be added in the step 1) may vary with a composition formula of a PZT-PNN piezoelectric material to be prepared (for example, ratio between PZT and PNN). It is appreciated that the piezoelectric material for low sintering have a composition within the composition range of the morphotropic phase boundary (MPB). The piezoelectric material for low sintering can show excellent electrical properties such as piezoelectric property in the MPB composition range compared to other composition ranges.

The raw material may be mixed in a jar for 12-24 hours in the step 1). Here, the raw material can be wet-mixed in a solvent which can be selected readily by a person skilled in the art. Also, zirconia balls can be added in the jar to mix and grind the raw materials at the same time.

In the step 2), the mixture of the ground and mixed raw materials can be calcined at a temperature range of 700-1000° C. for 2-5 hours but the temperature range and calcination time are not limited thereto. The temperature range and calcination time can be determined based on volatilization degree of the raw material and crystalline phase to be generated after calcination.

In the step 3), the calcined mixture can be milled by adding zirconia balls in the jar which is similar to that in step 1) and the milled mixture can be sieved to provide powders having uniform crystalline phase.

In the step 4), the sieved powder can be pressure molded and sintered to provide desired piezoelectric material, wherein the sintering can be performed at 950° C. or lower, preferably 900° C. or lower, more preferably 875° C. or lower for 2-8 hours.

In an embodiment of the present invention, the piezoelectric material for low sintering may further comprise 0.1 to 10 wt % of at least one oxide chosen from PbO, CuO, ZnO and MnO₂ with respect to the total weight of the piezoelectric material.

As described above, the oxide can be added after calcinating the mixture of the raw material (the step 2)) and can preferably function as a sintering aid to lower the sintering temperature by providing liquid phase sintering properties to the piezoelectric material. The oxide can be at least one chosen from PbO, CuO, ZnO, MnO₂, MnCO₃, SiO₂ and Pb₃O₄ but it is not limited thereto. In addition, preferably, the oxide can increase density and piezoelectric property of the piezoelectric material to be prepared after sintering.

In an embodiment of the present invention, the piezoelectric material for low sintering can has a glass transition temperature(Tg) of 280-320° C. or higher and a coercive electric field of 10 kV/cm or higher in the composition range satisfying the composition formula of (1-x)Pb(Zr_{(1-y)}Ti_{y})O₃-xPb(Ni_{1/3}Nb_{2/3})O₃ (0.10≦x≦020, 0.40<y<0.70).

In general, the processing temperature where the piezoelectric property of the piezoelectric material does not change is half the value of the glass transition temperature (Tg/2). For example, the processing temperature to combine a device made of the piezoelectric material to a vibrator or to stack the piezoelectric material with an electrode is about 150° C. or higher so that the glass transition temperature of the piezoelectric material should be about 300° C. or higher.

Accordingly, the glass transition temperature of the piezoelectric material is preferably 280° C. or higher, more preferably 290° C. or higher, further more preferably 300° C. or higher in the composition range satisfying the composition formula of (1-x)Pb(Zr_{(1-y)}Ti_{y})O₃-xPb(Ni_{1/3}Nb_{2/3})O₃ (0.10≦x≦0.20, 0.40<y<0.70).

In general, when an electric field having a coercive electric field value or higher is applied in an opposite direction after poling the piezoelectric material, it causes depoling to take away the piezoelectric property of the piezoelectric material. For example, the electric field applied to maintain stable performance of a piezoelectric actuator with the piezoelectric property of the piezoelectric material is 10 kV/cm (applying 100 V per 100 μm) or higher.

Thus, the coercive electric field value of the piezoelectric material is preferably 10 kV/cm or higher in the composition range satisfying the composition formula of (1-x)Pb(Zr_{(1-y)}Ti_{y})O₃-xPb(Ni_{1/3}Nb_{2/3})O₃ (0.10≦x≦0.20, 0.40<y<0.70).

In an embodiment of the present invention, the piezoelectric material for low sintering can have perovskite structure in the composition range satisfying the composition formula of (1-x)Pb(Zr_{(1-y)}Ti_{y})O₃-xPb(Ni_{1/3}Nb_{2/3})O₃ (0.10≦x≦0.20, 0.40<y<0.70)

As described above, the perovskite structure is crystal structure of compounds represented by the formula RMX₃ and piezoelectric materials having the perovskite structure are piezoelectric phase having the piezoelectric property. In general, the crystal structure of the piezoelectric material is directly related to the piezoelectric property, and particularly, the presence of the second phase in the piezoelectric material causes a decrease in the piezoelectric property. After sintering the piezoelectric material, any decreasing factor in the piezoelectric property of the piezoelectric material can be determined by analyzing the crystal structure (the presence or absence of the second phase).

According to an embodiment of the present invention, the piezoelectric materials for low sintering may have a perovskite structure which does not have the second phase in the composition range satisfying the composition formula of (1-x)Pb(Zr_{(1-y)}Ti_{y})O₃-xPb(Ni_{1/3}Nb_{2/3})O₃ (0.10≦x≦0.20, 0.40<y<0.70).

According to another aspect of the present invention, there may be provided piezoelectric devices comprising the piezoelectric materials for low sintering. Examples of the piezoelectric devices include ultrasonic transducers, piezoelectric actuators (d₃₃ type, d₃₁ type, etc.), piezoelectric sensors, high efficient capacitors and dielectric filters but it is not limited thereto.

In an embodiment of the present invention, the piezoelectric device may be a piezoelectric actuator. The actuator includes the piezoelectric material for low sintering of embodiments of the present invention and the piezoelectric material is surrounded by a conductive electrode. When a voltage is applied between the conductive electrodes, the actuator leads to piezoelectric strain due to the piezoelectric material.

Hereinafter, although more detailed descriptions will be given by examples, those are only for explanation and there is no intention to limit the invention.

### Examples

### 1. Method for Preparing a Piezoelectric Material

As described above, a piezoelectric material for low sintering having a composition formula of (1-x)Pb(Zr_{(1-y)}Ti_{y})O₃-xPb(Ni_{1/3}Nb_{2/3})O₃ (0.10≦x≦0.20, 0.40<y<0.70) was prepared by using the Columbite method. PbO, ZrO₂, TiO₂, NiO, Nb₂O₅ as raw materials were added in a nylon jar with zirconia balls and then a solvent was added to mix for 12 hours. After mixing, the mixture of the raw materials were calcined at a temperature of 800° C. for 2 hours.

After calcination, amount of the raw materials was controlled to have the composition formulas of the piezoelectric material to be prepared shown in the following Table 1.

TABLE 1

| Category | Composition formula |
|---|---|
| Example 1 | 0.90Pb(Zr_{(1-y)}Ti_{y})O₃—0.10Pb(Ni_{1/3}Nb_{2/3})O₃ |
| Example 2 | 0.85Pb(Zr_{(1-y)}Ti_{y})O₃—0.15Pb(Ni_{1/3}Nb_{2/3})O₃ |
| Example 3 | 0.80Pb(Zr_{(1-y)}Ti_{y})O₃—0.20Pb(Ni_{1/3}Nb_{2/3})O₃ |
| Comparative | 1.00Pb(Zr_{(1-y)}Ti_{y})O₃ |
| Example 1 | |
| Comparative | 0.97Pb(Zr_{(1-y)}Ti_{y})O₃—0.03Pb(Ni_{1/3}Nb_{2/3})O₃ |
| Example 2 | |
| Comparative | 0.94Pb(Zr_{(1-y)}Ti_{y})O₃—0.06Pb(Ni_{1/3}Nb_{2/3})O₃ |
| Example 3 | |
| Comparative | 0.91Pb(Zr_{(1-y)}Ti_{y})O₃—0.09Pb(Ni_{1/3}Nb_{2/3})O₃ |
| Example 4 | |
| Comparative | 0.78Pb(Zr_{(1-y)}Ti_{y})O₃—0.22Pb(Ni_{1/3}Nb_{2/3})O₃ |
| Example 5 | |
| Comparative | 0.70Pb(Zr_{(1-y)}Ti_{y})O₃—0.30Pb(Ni_{1/3}Nb_{2/3})O₃ |
| Example 6 | |
| Comparative | 0.60Pb(Zr_{(1-y)}Ti_{y})O₃—0.40Pb(Ni_{1/3}Nb_{2/3})O₃ |
| Example 7 | |

The calcined mixture was added in the nylon jar to be milled using zirconia balls and sieved to provide powders having uniform crystalline phase. The sieved powder was pressure molded and then sintered at 875° C. for 2 hours.

### 2. Analysis on Properties of a Piezoelectric Material According to the Amount of PNN in the Total Composition

Glass transition temperatures, coercive electric fields (Ec) and piezoelectric constants (d₃₁) of piezoelectric materials prepared according to Examples (Examples 1-3 and Comparative Examples 1-7) were determined. The glass transition temperature was determined using a differential scanning calorimeter (DSC), the coercive electric field was determined using a impedance analyzer and the piezoelectric constant was determined using a piezoelectric constant measuring instrument. The result was summarized in the following Table 2.

TABLE 2

| | Glass transition | Coercive electric | Piezoelectric |
|---|---|---|---|
| | temperature (Tg) | field (E_{c}) | constant (d₃₁) |
| Category | (° C.) | (kV/cm) | (pC/N) |
| Example 1 | 310 | 11 | −200 |
| Example 2 | 305 | 10 | −215 |
| Example 3 | 300 | 10 | −220 |
| Comparative | 340 | 14 | −130 |
| Example 1 | | | |
| Comparative | 330 | 12 | −140 |
| Example 2 | | | |
| Comparative | 320 | 12 | −170 |
| Example 3 | | | |
| Comparative | 315 | 11 | −190 |
| Example 4 | | | |
| Comparative | 270 | 9 | −225 |
| Example 5 | | | |
| Comparative | 220 | 8 | −230 |
| Example 6 | | | |
| Comparative | 196 | 7 | −235 |
| Example 7 | | | |

Referring to the Table 2, it is noted that the glass transition temperature and the coercive electric field become decreased, while the piezoelectric constant (d₃₁) is increased, as the content of PNN in the total composition of the piezoelectric material is increased. For example, when the content of PNN is increased from 0% (Comparative Example 1) to 9% (Comparative Example 4), the glass transition temperature is decreased from 340° C. to 315° C. and the coercive electric field is decreased from 14 kV/cm to 11 kV/cm, while the piezoelectric constant (d₃₁) is increased from −130 pC/N to −190 pC/N.

As the content of PNN in the total composition of the piezoelectric material is decreased, it shows favorable effects on the glass transition temperature and the coercive electric field, while it shows adverse effect on the piezoelectric property or the displacement property since it is needed to apply higher voltage to generate the same displacement with decreasing the content of PNN.

Therefore, as described above, it is critical to maintain the glass transition temperature to be 280° C. or higher, the coercive electric field to be 10 kV/cm or higher and the piezoelectric constant (d₃₁) to be about −200 pC/N in order to prevent depoling while the electric field is applied without any change in the properties of the piezoelectric material at the processing temperature of 150° C. or lower.

### 3. Analysis on the Properties of a Piezoelectric Material According to the Ratio Ti/Zr of PZT in the Total Composition

Properties of piezoelectric materials having a composition formula of 0.80Pb(Zr_{(1-y)}Ti_{y})O₃-0.20Pb(Ni_{1/3}Nb_{2/3})O₃ sintered at a low temperature of 875° C. and prepared according to Example 3 were determined. The result was summarized in the following Table 3.

TABLE 3

| Category | 0.80Pb(Zr_{(1-y)}Ti_{y})O₃—0.20Pb(Ni_{1/3}Nb_{2/3})O₃ | | | | |
|---|---|---|---|---|---|
| y | 0.505 | 0.510 | 0.515 | 0.520 | 0.525 |
| Density | 7.94 | 7.93 | 7.92 | 7.94 | 7.92 |
| (g/cm³) | | | | | |
| d₃₃ | 357 | 383 | 491 | 514 | 477 |
| (pC/N) | | | | | |
| Kₚ | 0.62 | 0.64 | 0.66 | 0.65 | 0.65 |
| k₃^{T} | 1,146 | 1,450 | 2,009 | 2,450 | 2,472 |
| (@ 1 kHz) | | | | | |

(1) Determination of Density of Piezoelectric Materials

Density of piezoelectric materials was determined according to Archimedes method (ASTM C373-71). Sintering degree of piezoelectric materials was determined by measuring density (density or relative density of the piezoelectric materials) after sintering the piezoelectric materials. The sintering degree of piezoelectric materials has direct relevance with the piezoelectric property. When sintering of the piezoelectric material is not enough, the desired theoretical piezoelectric property can be deteriorated or cannot show at all.

The sintering degree of piezoelectric material which is the density after sintering the piezoelectric material becomes decreased as the sintering temperature is lowered. Also, when the sintering temperature exceeds an appropriate temperature, the density tends to decrease. Therefore, it is critical to determine an appropriate sintering temperature for the piezoelectric material having a particular composition formula.

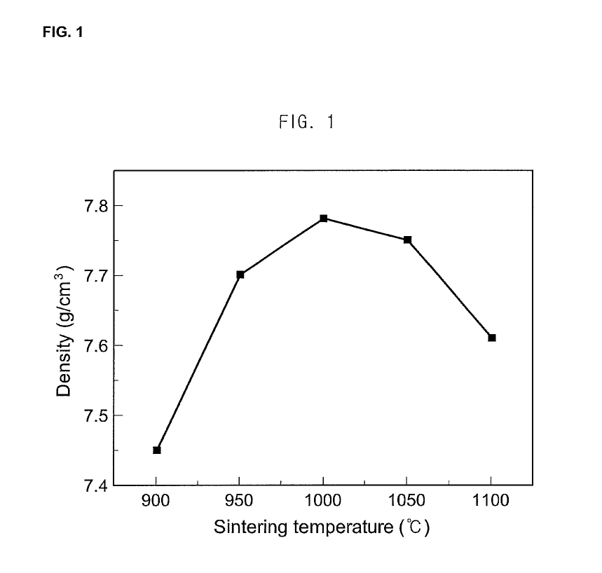

Referring to FIG. 1 illustrating density changes according to sintering temperature of a PZT-PZN-based piezoelectric material (Materials Letters 58 (2004), 1508-1512), it is noted that sintering at a high temperature of about 1000° C. is required in order to obtain near the theoretical density 7.8 g/cm³ of PZT-PZN. On the other hand, the piezoelectric materials according to Examples of the present invention show density of 7.9 g/cm³ or higher which is close to the theoretical density 8.0 g/cm³ of PZT-PNN at a low sintering temperature of 875° C. regardless of changes in Ti/Zr ratio.

(2) Determination of Dielectric and Piezoelectric Properties of Piezoelectric Materials

Dielectric and piezoelectric properties of piezoelectric materials were determined using a piezoelectric charge constant measuring instrument and an impedance analyzer, respectively. Unlike density of the piezoelectric material, various dielectric and piezoelectric properties such as piezoelectric charge constant (d₃₃), electromechanical coupling factor (kₚ) and dielectric constant (k₃^{T}) were related to changes in Ti/Zr ratio.

Piezoelectric charge constant (d₃₃), electromechanical coupling factor (kₚ) and dielectric constant (k₃^{T}) were shown a tendency to increase in general as y increases, and particularly, piezoelectric charge constant (d₃₃) and dielectric constant (k₃^{T}) were shown significantly high in the region of y≧0.515.

### 4. Analysis of Piezoelectric Material Structure (XRD)

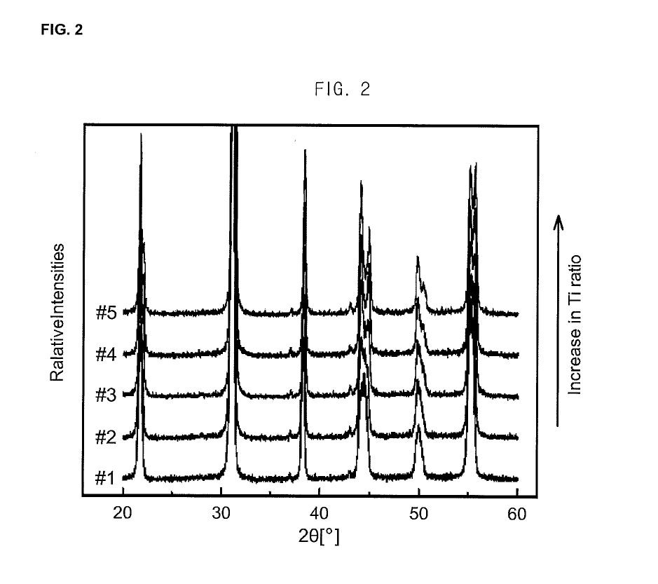

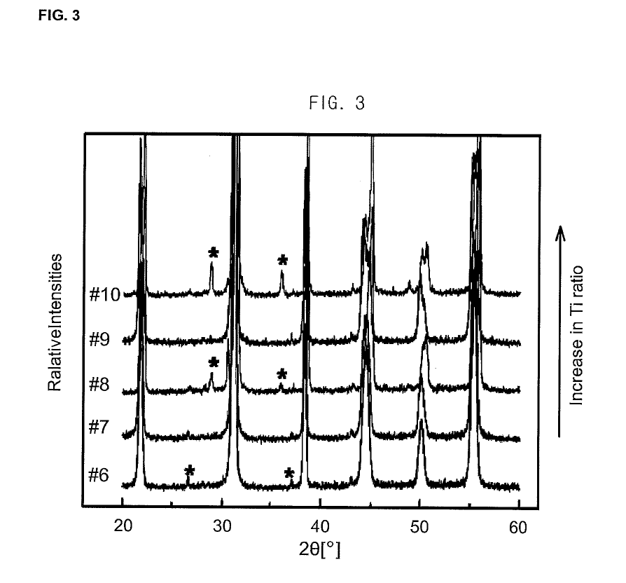

The presence of the second phase in the piezoelectric material having the perovskite crystals structure causes decrease in the piezoelectric property so that the crystal structure (the presence or absence of the second phase) after sintering of the piezoelectric material was analyzed using X-ray diffractometer (XRD). The result was illustrated in FIGS. 2 and 3.

Referring to XRD graphs in FIGS. 2 and 3, it is noted that the piezoelectric material of Example 3 of the present invention shows pure perovskite structure without the second phase (FIG. 2), while Comparative Example of the composition formula of (1-x)Pb(Zr_{(1-y)}O₃-xPb(Ni_{1/3}Nb_{2/3})O₃ in which x is 0.35 shows the non-piezoelectric second phase (*) (FIG. 3). The second phase peak (*) is corresponding to Pb₃Nb₄O₁₃ which is pyrochlore and the presence thereof deteriorates the piezoelectric property.

As described above, the piezoelectric materials according to the present invention show excellent piezoelectric property even at a low sintering temperature of 950° C. or lower. Particularly, the piezoelectric materials according to the present invention show not only significant improvements in density and glass transition temperature but also high properties such as piezoelectric charge constant, electromechanical coupling factor, mechanical quality factor and the like.

While it has been described with reference to particular embodiments, it is to be appreciated that various changes and modifications may be made by those skilled in the art without departing from the spirit and scope of the embodiment herein, as defined by the appended claims and their equivalents. As such, many embodiments other than that set forth above can be found in the appended claims.

1. A piezoelectric material for low sintering having a composition formula of (1-x)Pb(Zr_{(1-y)}Ti_{y})O₃-xPb(Ni_{1/3}Nb_{2/3})O₃ (0.10≦x≦0.20, 0.40<y<0.70).

2. The piezoelectric material for low sintering according to claim 1, wherein the composition formula is 0.80Pb(Zr_{(1-y)}Ti_{y})O₃-0.20Pb(Ni_{1/3}Nb_{2/3})O₃ (0.40<y<0.70).

3. The piezoelectric material for low sintering according to claim 1, wherein the piezoelectric material for low sintering is selected to have a composition in the composition range of the morphotropic phase boundary.

4. The piezoelectric material for low sintering according to claim 1, further comprising 0.1 to 10 wt % of at least one oxide selected from PbO, CuO, ZnO and MnO₂ with respect to the total weight of the piezoelectric material.

5. The piezoelectric material for low sintering according to claim 1, wherein the piezoelectric material for low sintering has a glass transition temperature(Tg) of 280-320° C. or higher.

6. The piezoelectric material for low sintering according to claim 1, wherein the piezoelectric material for low sintering has a coercive electric field of 10 kV/cm or higher.

7. The piezoelectric material for low sintering according to claim 1, wherein the piezoelectric material for low sintering has perovskite structure.

8. A piezoelectric actuator comprising the piezoelectric material for low sintering according to claim 1.

9. The piezoelectric material for low sintering according to claim 2, wherein the piezoelectric material for low sintering is selected to have a composition in the composition range of the morphotropic phase boundary.

10. The piezoelectric material for low sintering according to claim 2, further comprising 0.1 to 10 wt % of at least one oxide selected from PbO, CuO, ZnO and MnO₂ with respect to the total weight of the piezoelectric material.

11. The piezoelectric material for low sintering according to claim 2, wherein the piezoelectric material for low sintering has a glass transition temperature(Tg) of 280-320° C. or higher.

12. The piezoelectric material for low sintering according to claim 2, wherein the piezoelectric material for low sintering has a coercive electric field of 10 kV/cm or higher.

13. The piezoelectric material for low sintering according to claim 2, wherein the piezoelectric material for low sintering has perovskite structure.

14. A piezoelectric actuator comprising the piezoelectric material for low sintering according to claim 2.
